(19) United States
(12) Patent Application Publication
(10) Pub. No.: US 2021/0150867 A1
(43) Pub. Date: May 20, 2021

(54) SYSTEMS AND METHODS OF INTRUSION DETECTION FOR RACK ENCLOSURES

(71) Applicant: SCHNEIDER ELECTRIC IT CORPORATION, West Kingston, RI (US)

(72) Inventors: Stephen Paul Linder, Medford, MA (US); Kesavan Yogeswaran, Somerville, MA (US)

(21) Appl. No.: 16/616,798

(22) PCT Filed: Jun. 27, 2018
(86) PCT No.: PCT/US2018/039686

§ 371 Date: Nov. 25, 2019

Related U.S. Application Data
(60) Provisional application No. 62/525,900, filed on Jun. 28, 2017.

(51) Int. Cl. G08B 13/196; G06T 7/11; H04N 7/18; H04N 5/225; H04N 5/247

(52) U.S. Cl. CPC G08B 13/19602; G06T 7/11; H04N 7/181; G06T 2207/10048; H04N 5/247; G06T 2207/30232; H04N 5/2256

(57) ABSTRACT

Systems and methods of intrusion detection into a rack enclosure are disclosed. An example method may include, extracting a projected light terminator image from a captured image, performing image correction operations on the projected light terminator image, processing the projected light terminator image utilizing image processing operations to determine a corrected projected light terminator image, determining a collection of image segments based on the corrected projected light terminator image, establishing one or more baseline image metrics of the collection of the image segments, evaluating the one or more baseline image metrics for changes with operational image segment characteristics, and communicating any baseline image metric changes to a management device.

### CROSS-REFERENCE TO RELATED APPLICATION

This application claims priority to and benefit from the following provisional patent application: U.S. Provisional Application Ser. No. U.S. 62/525,900 titled “Systems and Methods of Intrusion Detection for Rack Systems” filed on Jun. 28, 2017. The entire contents of this aforementioned patent application are expressly incorporated by reference herein.

### BACKGROUND OF THE DISCLOSURE

### Field of the Invention

Embodiments of the present disclosure relate generally to systems and methods of intrusion detection, and more specifically to systems and methods for intrusion detection for rack enclosures.

### Description of Related Art

Rack enclosures and rack enclosure systems are generally used to receive and store electronic equipment and accessories to that equipment. One challenge related to the use of rack enclosures and rack enclosure systems is security of the contents enclosed within a rack or rack system. Security concerns include physically accessing the contents of the rack enclosure or rack enclosure system.

### SUMMARY OF THE DISCLOSURE

Systems and methods of intrusion detection into a rack enclosure are disclosed. An example method may comprise, extracting a projected light terminator image from a captured image, performing image correction operations on the projected light terminator image, processing the projected light terminator image utilizing image processing operations to determine a corrected projected light terminator image, determining a collection of image segments based on the corrected projected light terminator image, establishing one or more baseline image metrics of the collection of the image segments, evaluating the one or more baseline image metrics for changes with operational image segment characteristics, and communicating any baseline image metric changes to a management device.

System of detecting intrusion into a rack enclosure may comprise, a processor configured to extract a projected light terminator image from a captured image; perform image correction operations on the projected light terminator image; process the projected light terminator image utilizing image processing operations to determine a corrected projected light terminator image; determine a collection of image segments based on the corrected projected light terminator image; establish one or more baseline image metrics of the collection of image segments; evaluate the one or more baseline image metrics for changes with operational image segment characteristics; and communicate any baseline image metric changes to a management device.

Further embodiments of the system contemplate the corrected projected light terminator image may be processed to form a regular segmentation, semi-regular segmentation, demi-regular segmentation, and/or a segmented image. Additionally, a corrected projected light terminator image may be dynamically shifted in time.

Additional embodiments of a system of detecting intrusion into a rack enclosure may comprise, a rack enclosure; a projected light source; a video camera configured to capture and transmit image data; a Video Image Processing Module (VIPM) configured to receive and process image data from the video camera and communicate image data changes; and a management device configured to receive image data changes.

Further embodiments contemplate a plurality of rack enclosures, projected light sources, video cameras, and or VIPMs. Additionally, the plurality of projected light sources may utilize visible light and/or IR light.

Additional embodiments contemplate a method of detecting intrusion into a rack enclosure, which may comprise, extracting, a projected light terminator image from a captured image; performing, image correction operations on the projected light terminator image; processing, the projected light terminator image utilizing image processing operations to determine a corrected projected light terminator image; determining, a collection of image segments based on the corrected projected light terminator image; establishing, one or more baseline image metrics of the collection of image segments; evaluating, the one or more baseline image metrics for changes with operational image segment characteristics; and communicating, any baseline image metric changes to a management device.

Further embodiments of the method contemplate the corrected projected light terminator image may be processed to form a regular segmentation, semi-regular segmentation, demi-regular segmentation, and/or a segmented image. Additionally, a corrected projected light terminator image may be dynamically shifted in time.

### BRIEF DESCRIPTION OF THE DRAWINGS

These accompanying drawings are not intended to be drawn to scale. In the drawings, each identical or nearly identical component that is illustrated with various figures, are represented by a line numeral. For purposes of clarity, not every component may be labeled in every drawing. In the drawings:

FIG. 1 illustrates an isometric view of a rack intrusion detection system in accordance with various embodiments of this disclosure;

FIG. 2 illustrates an isometric view of a rack intrusion detection system for various rack enclosure types utilizing a projected light source in accordance with various embodiments of this disclosure;

FIG. 3 illustrates an isometric view of a rack intrusion detection system utilizing a projected light source and an intrusion device during a breach, in accordance with various embodiments of this disclosure;

FIG. 4A illustrates a front view of a rack intrusion detection system utilizing a plurality of projected light sources and a Video Image Processing Module (VIPM) in accordance with various embodiments of this disclosure;

FIG. 4B illustrates a front view of a rack intrusion detection system utilizing a plurality of projected light sources, a Video Image Processing Module (VIPM), and an intrusion device during a breach, in accordance with various embodiments of this disclosure;

FIG. 5A illustrates an isometric view of a rack intrusion detection system utilizing a plurality of projected light sources in accordance with various embodiments of this disclosure;

FIG. 5B illustrates an isometric view of a rack intrusion detection system utilizing a hierarchical plurality of projected light sources in accordance with various embodiments of this disclosure;

FIG. 6A illustrates a top view of projected light source image segments of a regular segmentation and detection in accordance with various embodiments of this disclosure;

FIG. 6B illustrates a top view of embodiments of projected light source image segments of a semi-regular segmentation and detection in accordance with various embodiments of this disclosure;

FIG. 6C illustrates a top view of embodiments of projected light source image segments of a demi-regular segmentation and detection in accordance with various embodiments of this disclosure;

FIG. 6D illustrates a top view of embodiments of projected light source image segments of a segmentation and detection in accordance with various embodiments of this disclosure;

FIG. 7 illustrates a system block diagram of a Video Image Processing Module (VIPM) detailing a rack intrusion detection system in accordance with various embodiments of this disclosure;

FIG. 8A illustrates a flow diagram detailing a baseline image segmentation and calibration process for a rack intrusion detection system in accordance with various embodiments of this disclosure;

FIG. 8B illustrates a flow diagram detailing a baseline image segment correction process for a rack intrusion detection system continued from FIG. 8A;

FIG. 8C illustrates a flow diagram detailing an image segment detection process for a rack intrusion detection system continued from FIG. 8B;

FIG. 9 illustrates an isometric view of a rack intrusion detection system including one camera and a plurality of projected light sources in accordance with various embodiments of this disclosure;

FIG. 10 illustrates an isometric view of embodiments of a rack intrusion detection system including a plurality of cameras and projected light sources in accordance with various embodiments of this disclosure;

FIG. 11 illustrates a functional block diagram of a general-purpose computer system in accordance with various embodiments of this disclosure; and

FIG. 12 illustrates a functional block diagram of a general-purpose storage system in accordance with the general-purpose computer system illustrated in FIG. 11.

### DETAILED DESCRIPTION OF THE DISCLOSURE

This disclosure is not limited in its application to the details of construction and the arrangement of components set forth in the following descriptions or illustrated by the drawings. The disclosure is capable of other embodiments and of being practiced or of being carried out in various ways. Also, the phraseology and terminology used herein is for description purposes and should not be regarded as limiting. The use of “including,” “comprising,” “having,” “containing,” “involving,” and variations herein, are meant to be open-ended, i.e. “including but not limited to.”

Computer equipment and related devices are generally located within a rack system. In additional to the infrastructure support system of power and cooling for the computer equipment, security of both the computer equipment and data it is responsible for storing, processing, and/or transacting is highly beneficial. While security in the form of physical and/or virtual barriers and/or personnel may be effective for facilities with dedicated computer equipment for a single party, comingling of computer equipment with various ownership frequently occurs at colocation facilities.

Generally, colocation centers are a form of data center where computer equipment, space, and infrastructure such as power, cooling, and security, are available for rental to retail, commercial, and other entities. Such a space is generally available to a variety of customers with computer equipment. It is highly desirable to maintain security for an entity's equipment to prevent computer equipment and/or data from that computer equipment being accessed accidentally or intentionally from an unauthorized party.

Limiting access to a room or rack enclosures utilizing video surveillance or security escorts to allow access to authorized equipment are example methods of security. These methods while effective can be resource intensive and require an individual to monitor a camera or provide an escort. Escorts into colocations may be preferred so any attempt to gain unauthorized access can be stopped immediately but are also resource intensive.

To address the problems of resource allocation, monitoring an environment, and immediate detection and notification of a potential or actual unauthorized access, autonomous detection system of a person and/or an object crossing into the interior space of a rack or other room or area, may be utilized as described in this disclosure. A detectable boundary may be placed proximate to an entry plane of a rack system. This boundary may give both a visual source to individuals in the vicinity while also serving as a component for an image processing solution. If the boundary is breached, an alert/notification may be generated and sent to security personnel or other actions may be initiated such as a power down of equipment or security lock down of the facility.

Advantages of the various embodiments contained herein include; an ability to process video images robustly yet with a minimum of computational processing power, reduced cost of system hardware, and faster processing speeds without sacrificing image fidelity using parallel processing utilizing multiple computers, multiple processors, or both. In concert and individually, the systems described herein facilitate these advantages and enable powerful methods for rack intrusion detection at a low cost. This trade-off of creating a cost reduced image processing system with selectively parallel processing discrete portions of a captured video image to determine if a boundary in three-dimensional space has been breached is a significant advantage over existing image processing and intrusion detection systems.

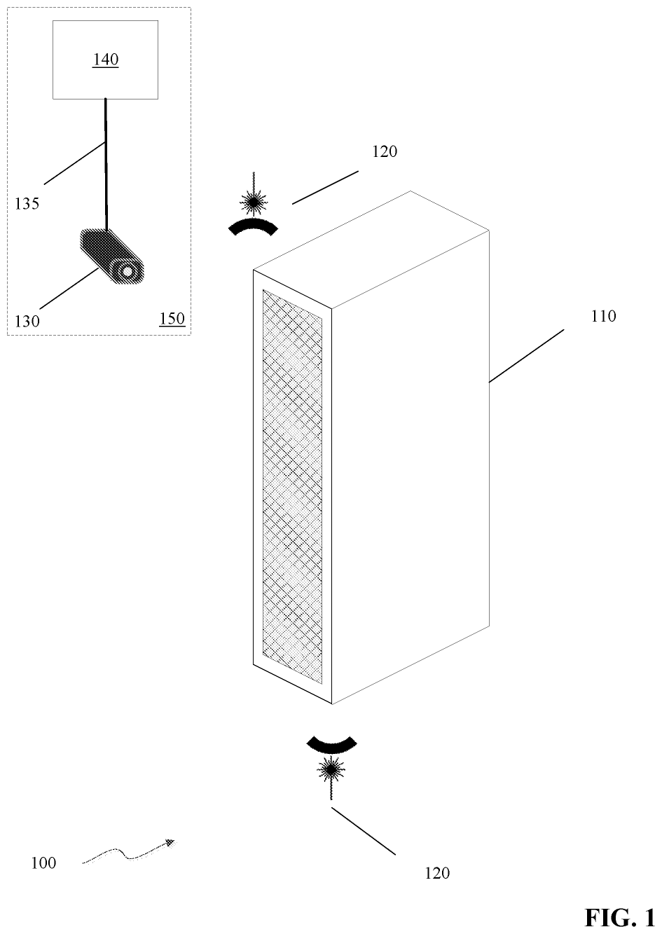

FIG. 1 illustrates an isometric view of a rack intrusion detection system 100 in accordance with various embodiments of this disclosure. One embodiment of a rack intrusion detection system 100 may include one or more rack enclosures 110 which may contain one or more assets to be secured, two or more projected light sources 120, one or more video cameras 130, and a Video Image Processing Module (VIPM) 140, connected by a data and/or power connection 135, such as Power Over Ethernet (POE) or other data only standard, wired or wireless in nature. Combinations of video cameras, data and/or power connections, and/or VIPM systems may be combined together to form a Video Image Processing System (VIPS) 150. Embodiments of the system may also include one or more computer systems to assist in facilitating the benefits of the disclosure such as communication to one or more management devices. It should be appreciated that the one or more rack enclosures 110 are not required to practice this disclosure. The one or more assets to be secured may be contained in a room, closet, building, and/or other physical space other than one or more rack enclosures 110.

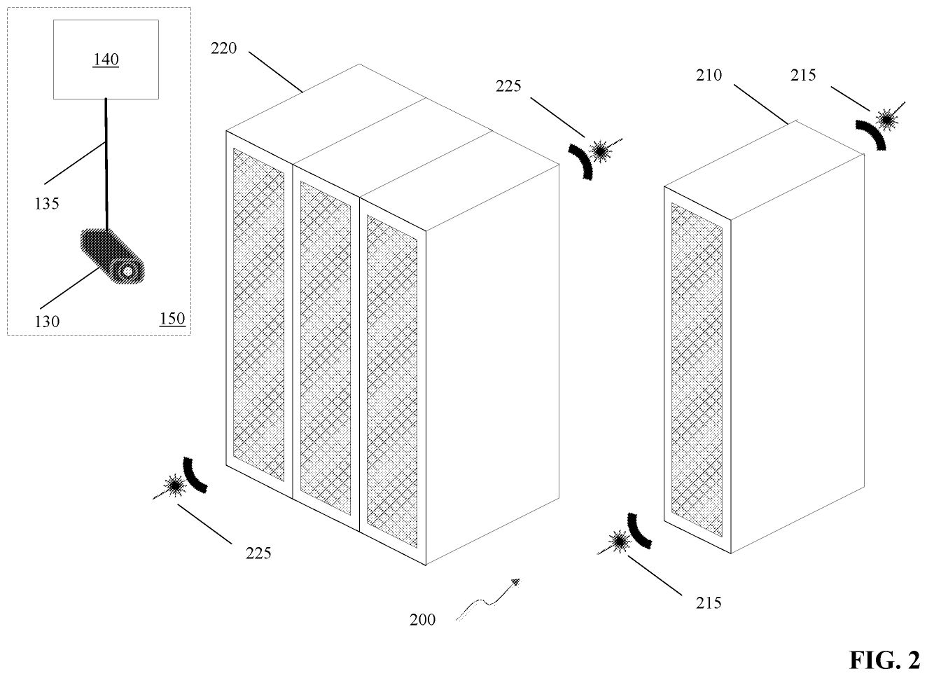

FIG. 2 illustrates an isometric view of a rack intrusion detection system for various rack enclosure types 200 in accordance with various embodiments of this disclosure. Various embodiments of a rack enclosure may be utilized in the system including a single rack enclosure 210 and two or more projected light sources 215, a plurality of rack enclosures 220 and two or more projected light sources 225, a VIPS 150, or other enclosures to store computer equipment.

Principles of the disclosure contemplate rack enclosures which are adjacent with each other such as various data center or colocation environments but also rack enclosures that are physically separate and apart from one another. Also contemplated are structures that may not house computer equipment but are adjacent to and/or associated with rack enclosures which do. Examples of such structures may be, but are not limited to, cable support structures, power and cooling duct and support structures, and/or infrastructure equipment to support the computer equipment such as power distribution and associated equipment.

Further, while embodiments of this disclosure contemplate a door to a rack enclosure which is perforated in nature other embodiments contemplate a solid surface such as a door, wall, and/or roof. Alternatively, no structure may exist in the space where detection is desired. Such cases may include a door threshold, open ceiling, or other such open structure.

It should be appreciated, while rack enclosures may be composed in various manners to accommodate the computer equipment it is designed to house, this disclosure contemplates autonomous intrusion detection absent a rack enclosure. Any enclosure, or other space may utilize embodiments of this system to autonomously detect an unauthorized breach or access of a system secured space. Further it is to be understood, that the secured space may be multi-dimensional, such as a two-dimensional surface or three-dimensional space, based on a variety of factors including, the application, asset(s) to be secured, and/or the particular system implementation.

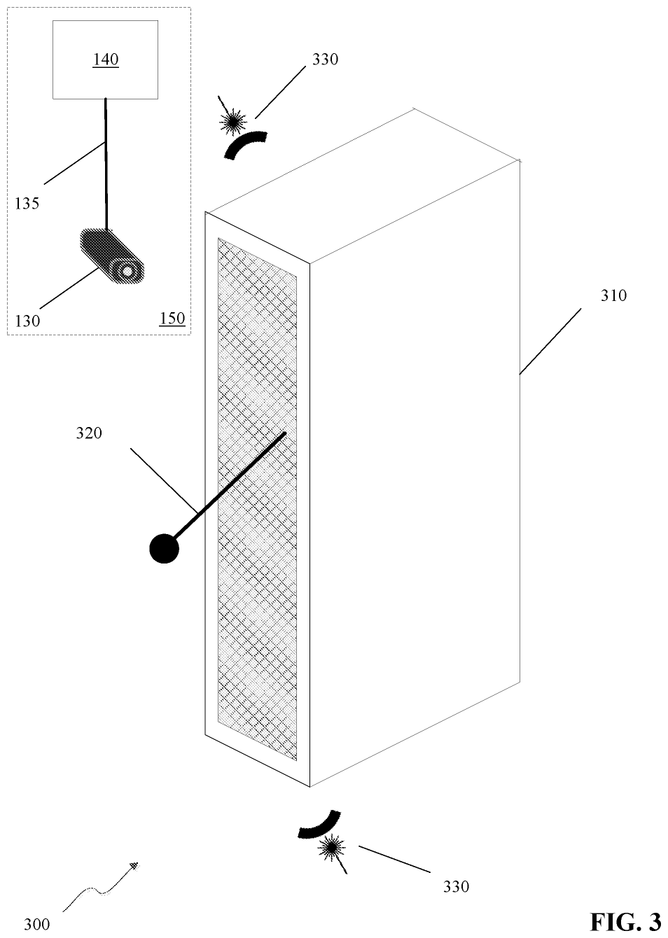

FIG. 3 illustrates an isometric view of a rack intrusion detection system utilizing a projected light source and an intrusion device 300 during a breach, in accordance with various embodiments of this disclosure. One significant problem this disclosure addresses is to provide detection of devices that intrude into a rack enclosure or other space. This intrusion can be into openings that exist in a rack enclosure, such as the open grate typically found in the front and rear doors of a rack enclosure, but also openings that are created by intentionally altering the rack enclosure to gain access.

Various embodiments of a rack enclosure may be utilized in the system including a single rack enclosure 310, a VIPS 150, and two or more projected light sources 330. An intrusion device 320 may be used to access equipment within the rack enclosure 310 to perform unauthorized operations, such as, but not limited to, depressing the reset button on a server to interrupt the operation. Such intrusion devices 320 may include devices such as straws, writing devices, coat hangers, and similar sized devices, of a small enough form to penetrate openings in a rack enclosure 310.

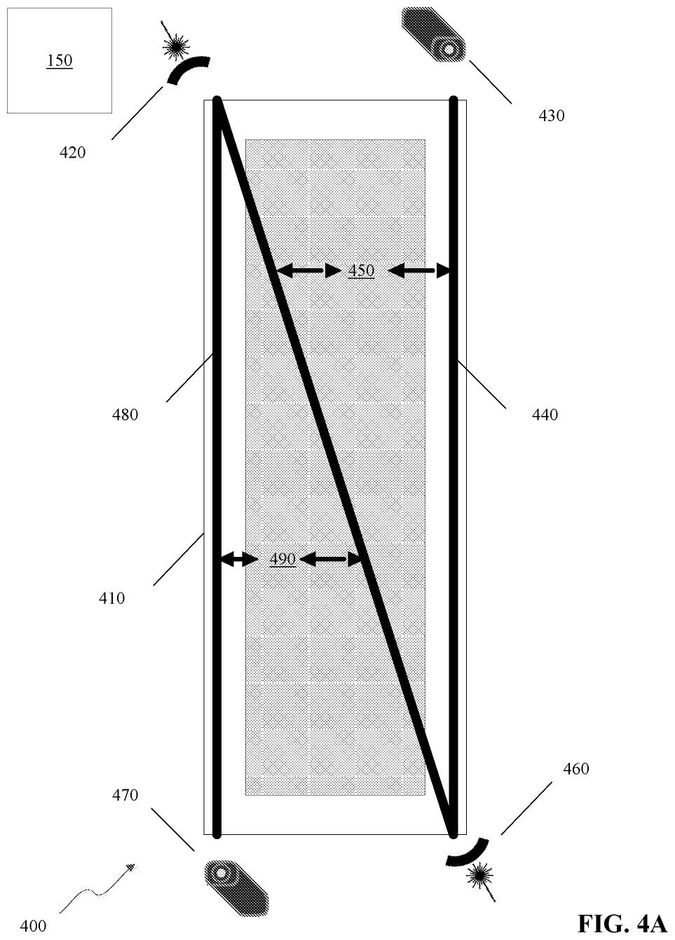

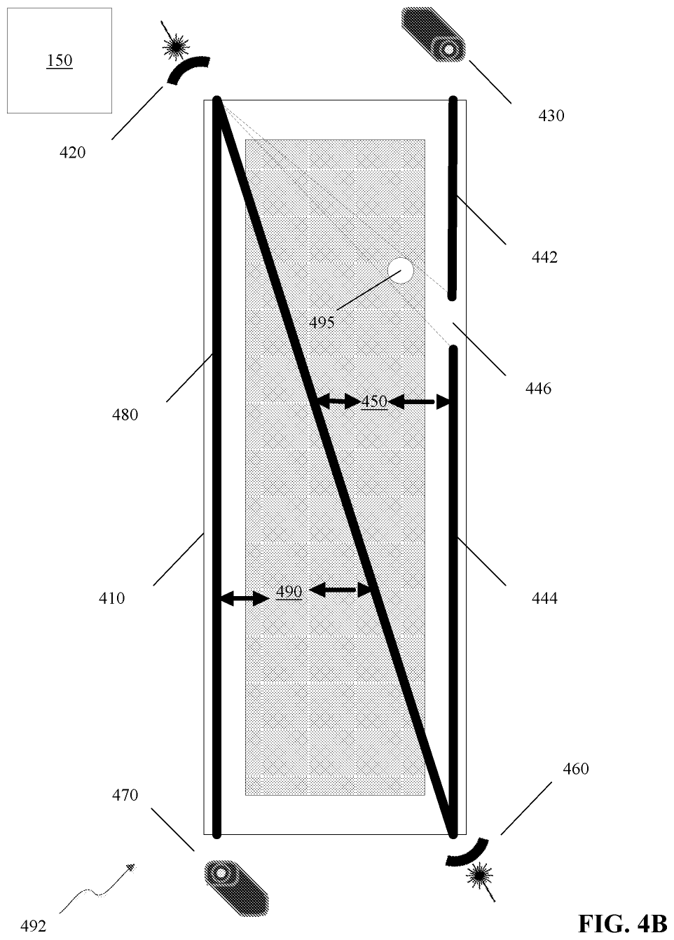

FIG. 4A illustrates a front view of a rack intrusion detection system utilizing a plurality of projected light sources and a Video Image Processing Module (VIPM) 400 in accordance with various embodiments of this disclosure. In one embodiment, a rack enclosure 410 may have more than one structured light source to project light onto a plane of the rack enclosure 410 where a door, or other rack panel, is located. A projected light source 420 when projected through a lens, such as, but not limited to, a Fresnel lens, to align the light to project a first light field 450 in the approximate dimensions of one half of a rack enclosure door. Associated camera 430 as part of a VIPS 150, observes a projected light output line from the projected light output 440 for any changes which indicate the possibility of a rack intrusion within the corresponding first light field 450.

Approximately the other half of the rack enclosure 410 may also have a projected light source 460 when projected through a lens, such as, but not limited to, a Fresnel lens to align the light to project a second light field 490 in the approximate dimensions of one half of a rack enclosure door. Associated camera 470 observes a projected light output line from the projected light output 480 for any changes which indicate the possibility of a rack intrusion within the corresponding second light field 490. Although two projected light sources are illustrated which project a light field to each cover approximately one half of a rack enclosure door, it is to be understood that other embodiments of the system are possible. For example, one, three, four, five, or more projected light sources are contemplated depending on the specific implementation.

FIG. 4B illustrates a front view of a rack intrusion detection system utilizing a plurality of projected light sources, a Video Image Processing Module (VIPM), and an intrusion device 495 during a breach 492, in accordance with various embodiments of this disclosure. In one embodiment, the intrusion device 495 is introduced into the rack enclosure 410. It should be appreciated than an intrusion device may be any physical object which breaks the plane of the projected light source. Such devices may include fingers, pencils, paperclips, or any apparatus to attempt to affect a physical touching of any equipment which is housed in the rack enclosure.

When the intrusion device 495 is introduced, the projected light source 420 is obstructed and an altered line segment 446 or other interruption of the project light source, is created for the segment of line associated with the projected light source 420. This altered line segment 446 may be in the form of a shadow or other disruption of the continuity of the projected light line. It should be appreciated, blocking a portion of the projected light source 420, will cause a distortion in the projected light output 440 (from FIG. 4A), which can be detected by the associated camera and VIPM and VIPS 150 systems. This altered line segment 446 when the image is captured by the VIPS 150 is also the projected light terminator image. Light from the projected source 420, is terminated or blocked by the intrusion device 495 causing a shadowed or altered image detectable to the VIPS 150. Detection of the altered line segment 446 is an indication an intrusion is occurring.

Corresponding line segments 442 and 444 exist where the projected light is not blocked. A projected light upper line segment 442 and projected light lower line segment 444 exist and are detected by the corresponding camera 430 in the VIPM system.

It all cases it should be appreciated that the projected light need not be within the human visible spectrum to be utilized in this disclosure. Projected light sources, camera technology, and VIPM systems may utilize sources outside of visible light such as, infra-red, and/or ultra-violet sources and detection methods.

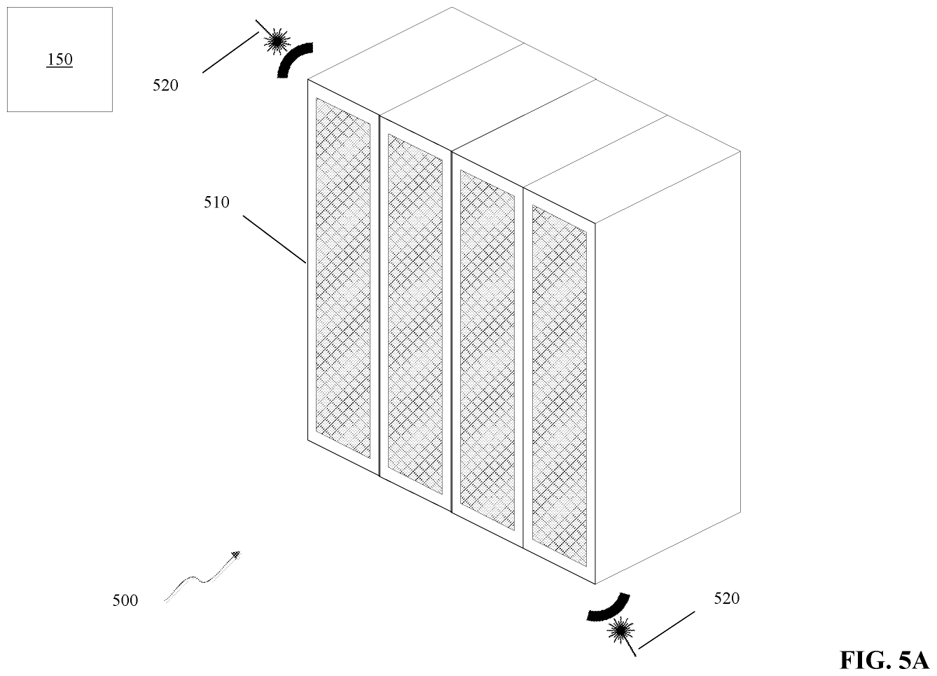

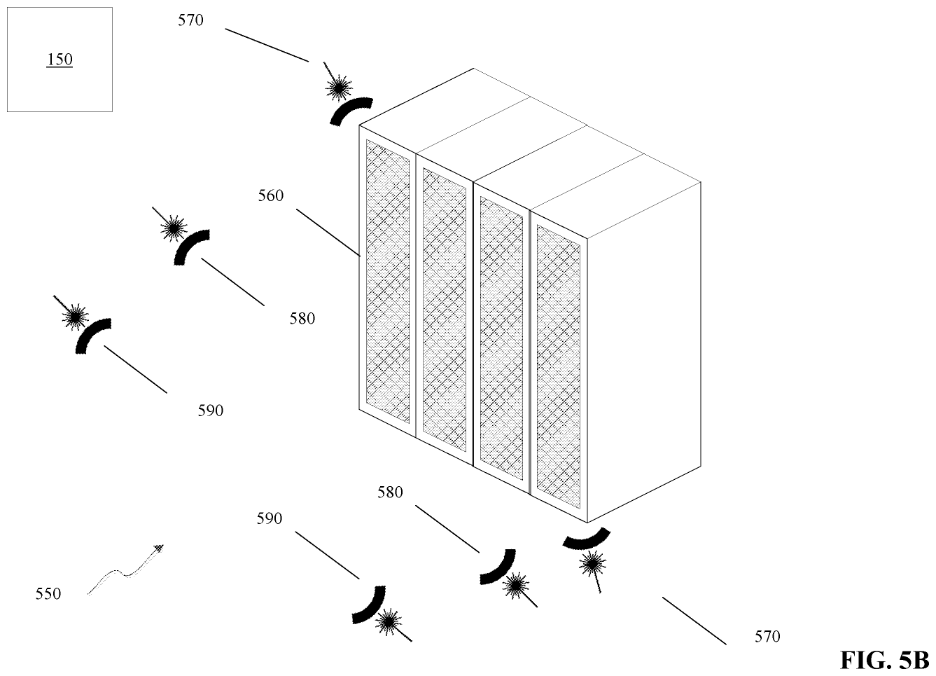

FIG. 5A illustrates an isometric view of a rack intrusion detection system 500 utilizing a plurality of projected light sources 520 in accordance with various embodiments of this disclosure. In this embodiment, a plurality of rack enclosures 510 has corresponding projected light sources 520 and a VIPS 150. Intrusion detection establishes an image from a security camera and a projected light source 520 where intrusion detection is to be monitored. In these implementations, the system can effectively provide a three-dimensional secured space around one or more assets based in part on where the projected light source is strategically situated.

The projected light source 520 initially defines a contrast to the background on which it is placed to facilitate system commissioning in developing a baseline detection image. The VIPM 150 utilizes such contrast to create a baseline image. This baseline image is utilized in a comparison to an operational image acquired post system commissioning. Pixels of the operational image or pixels in at least one segment of the operational image are compared to pixels of the baseline image or pixels in at least one segment of the baseline image of the projected light source 520. If the comparison of images identifies pixel changes in the boundary/secured area, the space surrounding the secured asset has been breached.

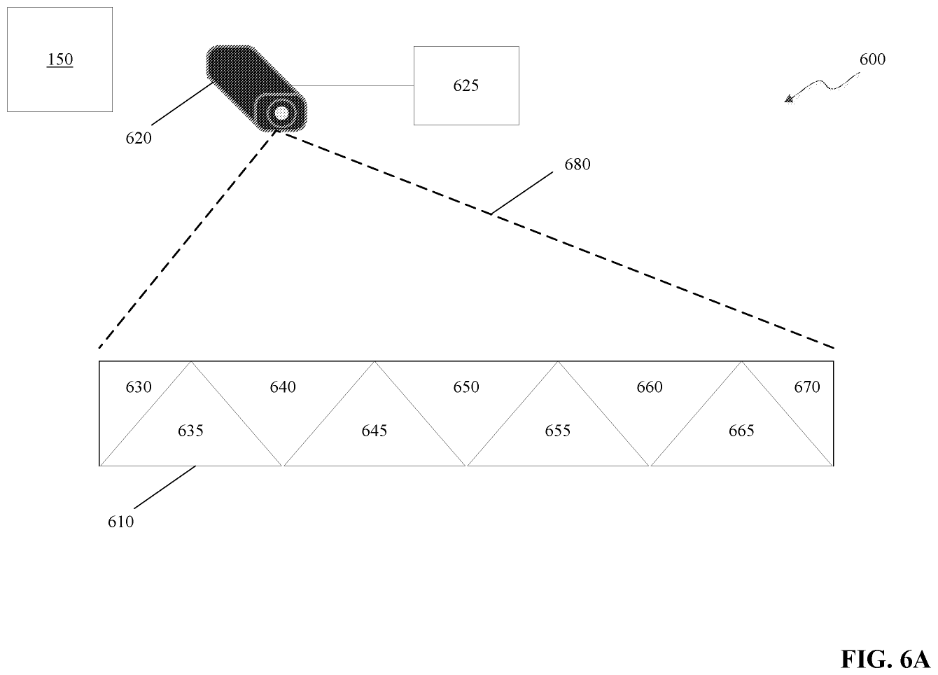

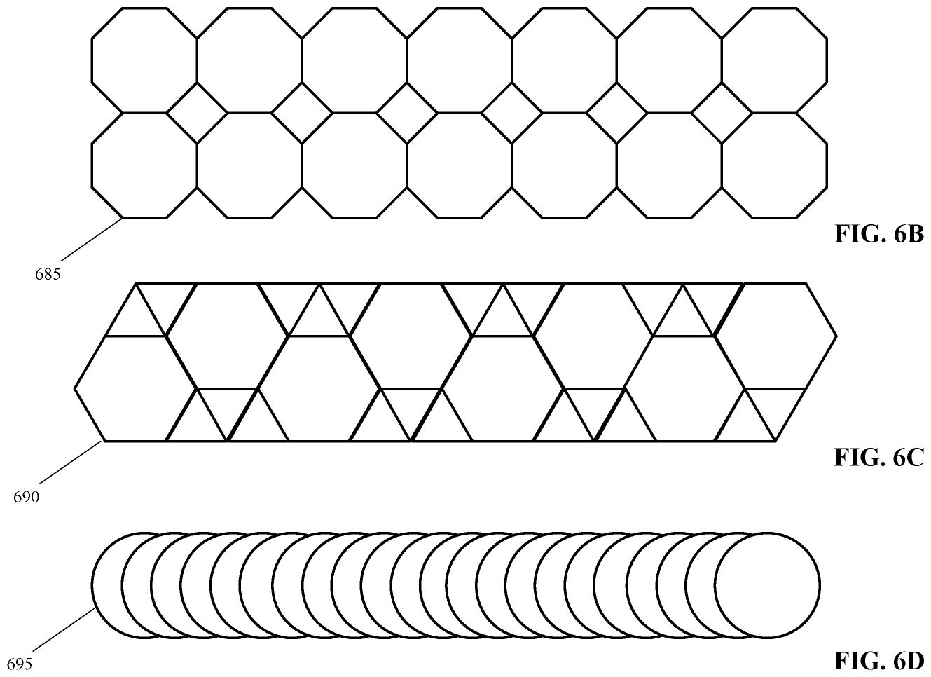

Examples of contrast to the background which may be implemented include, detecting contrast of the matte color, reflectance characteristics for Infra-Red (IR) and/or visual light, and/or illumination level. It should be appreciated this list is not exhaustive and other embodiments of contrast and contrast levels are possible. Aspects of image processing associated with breach detection will be described in more detail in FIGS. 6A-6C.

As one of many examples, the projected light source 520 may be composed of one or more lasers, or other projected light sources which may be placed at one or more strategic locations for use both as a visual guide to users and to facilitate creation of the projected light source 520 used to generate the baseline image used by the system during commissioning. The projected light source 520 contrasts with the floor or other surface which surrounds the projected light source 520 and be utilized by the VIPM 150 to calibrate and determine a baseline image for comparison during image breach detection operations. Once the calibration is complete, the projected light source 520 may remain in place and function both as a visual source for users and as part of the baseline for the system to compare operational images against. Although illustrated as a source projected on the rack surface of a data center, it is to be understood, other projected light source applications are possible for example, on walls, ceilings, cabinets, and/or other structures situated near or around the one or more assets and/or space to be secured.

A projected light source 520 may consist of media which provides a contrast to the surrounding environment. Examples of such media may include, but are not limited to, lasers, light projection devices such as lamps with a lens to focus the light, and/or other sources of projected light. It should be appreciated the projected light source 520 need not be static in nature and may change with time or other event, or series of events. For example, a system may be configured to change the method of detection, either periodically such as every hour, minute, day, week, or with a pre-defined triggering event, combination and/or series of triggering events. An example of a triggering event may be activation of a door sensor, security alarm, or audible alert sensor, such as a glass break monitor.

In an implementation, a laser line may be established at a predetermined time interval to act as projected light source 520 around one or more assets and/or within a space desired to be secured. Once this dynamic projected light source 520 is calibrated, and as necessary, corrected, the system will begin detection operations. Once the dynamic projected light source 520 is moved at the expiration of the predetermined time interval and/or triggering event, the system will recalibrate to the new location of the dynamic projected light source 520 and reinitiate image detection operations in the new projected light source 520 location.

It should also be appreciated that the dimensions of the one or more implemented projected light sources may be based on the operational environment and/or the secured asset(s) characteristics. No fixed dimensions are required to establish an effective projected light source 520. A determinative aspect of a projected light source 520 is that it may be detected by the VIPM during calibration. Once the system is calibrated and corrected as necessary, the projected light source 520 may be changed from the visible light spectrum to the invisible light spectrum for image detection operations. Depending on the implementation, a pair of projected light sources 520 may be used or more than two projected light sources may be used in coordination with each other to secure assets as illustrated in FIG. 5B.

Some embodiments contemplate the projected light source 520 may be changed from visible light spectrum after being recognized and calibrated by the intrusion detection system described herein. In such embodiments, while projected light sources are placed initially, they may be removed after commissioning to create an “invisible boundary” which remains detectable to the intrusion detection system.

FIG. 5B illustrates an isometric view of a rack intrusion detection system utilizing a hierarchical plurality of projected light sources 550 in accordance with various embodiments of this disclosure. In one embodiment, a plurality of rack enclosures 560 is demarked by an inner projected light source 570, a middle projected light source 580, and an outer projected light source 590 which may be utilized to create a hierarchy of projected light sources. Each projected light source may act independently or in coordination with the other and may serve as tiers of security.

In an embodiment, the outermost source represents a first in increasing levels of security and the innermost source representing the most severe security condition. It should be appreciated the relative distance between the plurality of sources may vary depending on a variety of operational and/or environmental factors. There is no need for the sources to be in proximity of each other as illustrated in FIG. 5B. Further, while three projected light sources are illustrated, there is no constraint to the number of projected light sources the system may utilize. It should also be appreciated that while FIG. 5B illustrates visible projected light sources, one, some, or all the projected light sources may change to the non-visible light spectrum once calibrated and corrected as necessary, for the image detection operation of the system.

As one of many examples, if intrusion breach is determined at the outer projected light source 590, the system may be configured to generate and transmit text messages to specified personnel. The system may also initiate, for example, an increased video frame rate or increased image resolution, to allow more granular video data of a higher quality to be captured. If the middle projected light source is breached, the system may also include initiation of an audible alarm. In one implementation, if the inner projected light source is breached, which may signify the most serious security condition, the computer equipment within the rack enclosures may be powered down to cause the computer equipment to be unusable.

Actions may be correlated to each projected light source in any order. Other actions depending on the particular implementation are possible in various sequences to create the desired security configuration for the rack enclosure, two-dimensional surface, or three-dimensional space, to be monitored. As one of many examples, timing between intrusion detection of boundaries may be utilized as one factor to determine what actions to take. If an individual breach the outer projected light source 590 an audible warning would occur. Further, a timer may be set where if a breach of the middle projected light 580 were to occur within a specified period of time (e.g. 5 seconds) of the breach of the outer boundary 590, any breach of the inner projected light 570 would result in an immediate shutdown to the computer equipment in the rack enclosure 560. However, if a longer interval than programed occurs (e.g. more than 5 seconds), other actions may be taken, such as a text message warning appropriate personnel of the security alert.

To realize the benefit of utilizing low end video detection systems, various methods may be utilized for video processing projected light source analysis to reduce the amount of processing power necessary to analyze a video image. One example implementation of processor reduction utilizes a segmentation of a captured image. Such a segmentation may take the form of a segmentation, or tiling process. Segmentation renders the selectively detected image of the projected light source into an arrangement of shapes closely fitting together. FIG. 6A illustrates a top view of projected light source image segments of a regular segmentation and detection 600 in accordance with various embodiments of this disclosure. Components of the VIPM and VIPS 150 to detect rack system intrusion may include a projected light source 610, a low-end video camera 620, and a VIPM 625. Another benefit realized is the reduced area of an image required to analyze to determine an intrusion of the rack enclosure.

Various advantages of the system described herein include cost effective hardware component designs and very fast processing times. Creating a low-end video detection system with selectively parallel processing, utilizing multiple computers, multiple processors, or both. discrete portions, such as segments, pixels, and/or pixels of particular image segments, of a captured video image to determine if a boundary in three-dimensional space has been intruded upon, is a significant advantage over existing video processing systems. These advantages may be realized in part due to the segmentation or tiling process of a projected light source 610.

The VIPM 150 implements the segmentation/segmentation process, renders the projected light source 610 into a series of geometric segments. Each individual segment is in turn processed, in series or in parallel, and not the image of the whole projected light source 610 and surrounding environment. Depending on the amount of changes within the image segment the need for processing power may be reduced. Further utilization of smaller processing elements may be accomplished. Relying on the parallel process of smaller, segment(s) of an image, and/or pixels within an image segment, reduces the amount of processing time substantially as opposed to processing a complete projected light source 610 image and the surrounding environment, which itself may be very large, or of an irregular shape.

A complete image of a projected light source 610 and surrounding environment and comparison to an operational image of that projected light source and surrounding environment, presents a large technical challenge due to the complexity of observing and rendering any image of a projected light source 610. Embodiments of the disclosure, utilizing projected light source 610 image segments, and/or pixels of image segments, definition, calibration, and comparison processes, create smaller, less complex VIPM processing requirements.

As a result of these less complex calculations to be performed by the VIPM 150, the video camera 620 utilized may have a wide range of frame rate and image resolution. An inexpensive video or web camera 620 with entry level characteristics may be utilized for robust intrusion detection within embodiments of the disclosure. Characteristics of this robust intrusion detection include increased image reliability and sensitivity, while lowering the rate of false alarms. It should be appreciated a low-end video camera 620 may define various characteristics known to video cameras such as image resolution, frame rate, image stabilization, and/or sensitivity in various light conditions. As one example, a video camera with a video capture resolution of 320×240 pixels, operating at 30 frames per second, without image stability or low light sensitivity may be utilized in some embodiments of the disclosed system to robustly detect intrusion.

As a second example, multiple video cameras may be utilized with dynamic image resolution. Each camera may normally operate at a low image resolution (e.g. 320×240 pixels) may be utilized at 30 frames per second. When a possible intrusion is detected by one camera, resolution of just that camera may increase in resolution, frame rate, and/or other camera characteristics to capture the event. This may, for example, have a benefit of minimizing any congestion for a communications port where multiple cameras may be connected and scanning at a high rate, simultaneously.

It should be appreciated, a video camera 620 with substantially improved characteristics such as 4K resolution, operating at 240 frames per second, with image stability and night vision capabilities may also be utilized in some embodiments of the disclosed system, however may correlate to substantially increased costs for some applications.

Embodiments of the disclosure discuss aspects of very fast processing times for a projected light source 610 as a result in part of various embodiments of segmenting the captured image. Embodiments of this segmentation process include the segmentation process. A reduction of processing times is accomplished through the example processes described in FIG. 6A-6C. As part of the process, each image of the projected light source 610 undergoes a segmentation process, whereby the projected light source 610 is rendered into an arrangement of image segments. In the case of segmentation, these shapes, may be regular, semi-regular, demi-regular, and may fit together with or without gaps between spaces. Additionally, the arrangement of shapes may overlap each other. Other embodiments of segmentation may not require the image segments to fit together or be regular, semi-regular, and/or demi-regular in shape.

FIG. 6A illustrates a projected light source 610 which has been deconstructed via the segmentation process, into a plurality of segments 630, 635, 640, 645, 650, 655, 660, 665, 670. While segments may be triangular as illustrated in FIG. 6A, many variations of shapes are possible including triangles, squares, and hexagons for a regular segmentation. Examples of semi-regular segmentations 685 are illustrated in FIG. 6B, demi-regular segmentations 690 in FIG. 6C, and other projected light source segmentations 695 in FIG. 6D where the segmented shapes overlap each other. Other segmentations types may produce other segment shapes including, but not limited to, circles, ellipses, and other curved shapes. A complete projected light source 610 need not be formed by straight lines, but may be curved as well.

The type of segmentation may depend on the projected light source 610 to be segmented. For example, a regular segmentation requires a single identical polygon to form the segments such as the triangle segments in the projected light source 610 illustrated in FIG. 6A. Other projected light source shapes may require alternate segmentation types.

Embodiments of the system also contemplate other methods of segmentation of a projected light source image in addition to the segmentation process described above. A result of such segmentation may result in a set of image segments which collectively cover the entire projected light source image. It should be appreciated these image segments may not be uniform in size or may not overlap with each other. Alternate embodiments of projected light source image segments may be non-uniform in size and do not overlap in accordance with various embodiments of this disclosure.

Characteristics of each image segment may or may not contain similar characteristics such as, but not limited to, number of pixels, color, and/or texture. Images may be segmented in a variety of methods including, but not limited to, thresholding, clustering, dual clustering, compression, histogram, edge, and/or region-growing methods.

It should be appreciated that only the portions of the projected light source 610 which are within a camera field of view 680 may be analyzed by that camera. Embodiments of the disclosure contemplate a plurality of cameras and/or a plurality of projected light sources which may be used in the system to detect intrusion in a large area, non-adjacent areas of a space to be secured, and/or to provide redundancy to an area already secured with the disclosed system.

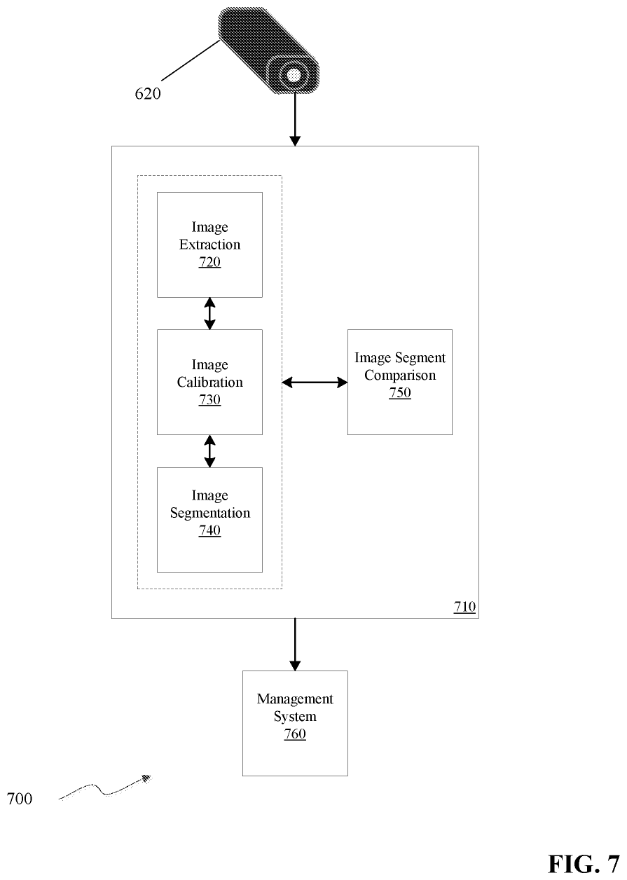

FIG. 7 illustrates a system diagram of a Video Image Processing Module (VIPM) 710 for a rack intrusion detection system 700 in accordance with various embodiments of this disclosure. A VIPM 710 may have inputs, such as a source of video from one or more cameras 620, and/or outputs that may include a management system 760 to further process any information which comes from the VIPM 710. In some embodiments, the management system 760 can embody one or more management devices that are configured to receive image data changes and provide alert(s) to one or more users.

A VIPM 710 may consist of several sub-modules. These modules may include an image extraction module 720, image and/or image segmentation calibration/correction module 730, image segmentation module 740, and/or an image segment comparison module 750. Image extraction, calibration/correction, and segmentation, may be grouped together to provide image and/or image segment refinement for use before and/or after the breach detection operations contemplated in the image segment comparison module 750.

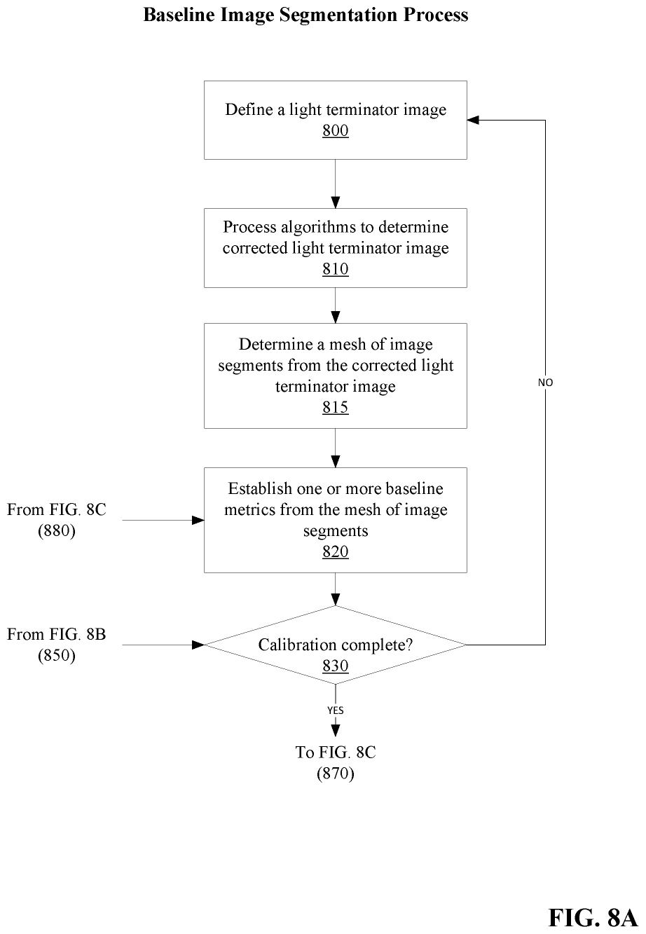

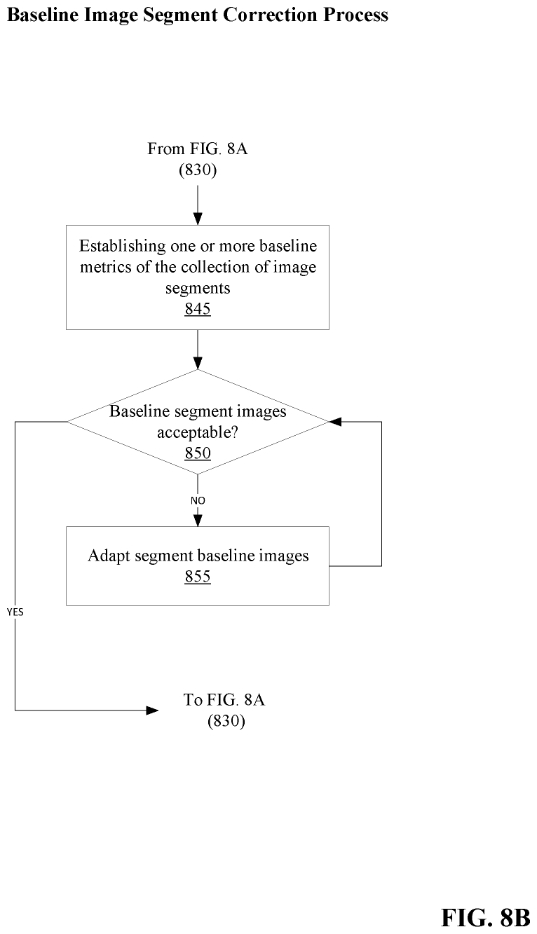

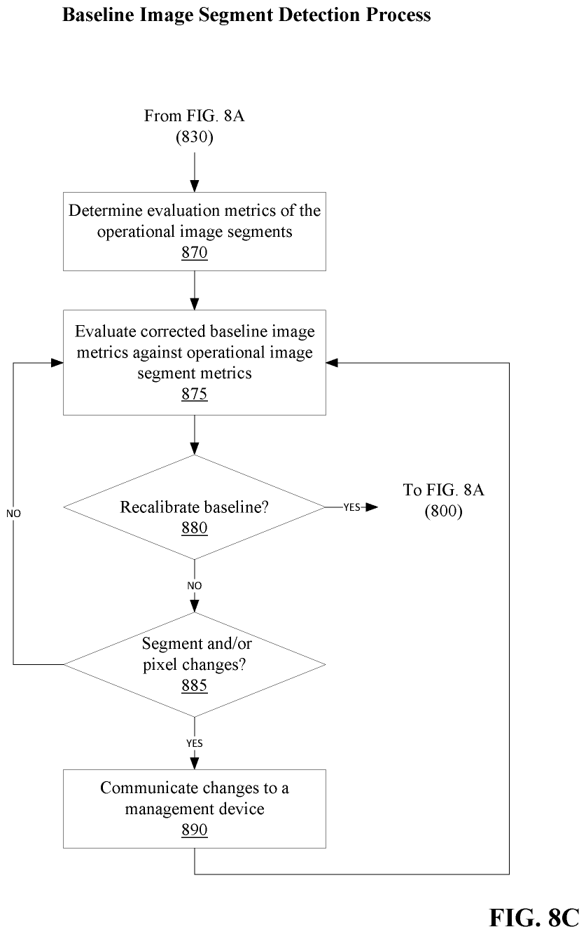

FIGS. 8A-8C illustrate examples of flow diagrams of a rack intrusion detection system in accordance with various embodiments of this disclosure. These methods include baseline image segment capture and calibration, baseline image segment correction, and image segment breach detection processing and logic flow. One example of this process may operate in two processing loops. A first process loop may capture, calibrate, and refine baseline image segments marked by a projected light source or other visible spectrum mark, which may be changed to the non-visible spectrum to create an invisible boundary. A second process loop may detect changes to the baseline image segments by comparing the calibrated and/or corrected baseline image segments to one or more operational image segments. It should be appreciated various embodiments of process flows exist.

FIG. 8A illustrates a flow diagram detailing aspects of a VIPM implementation baseline image segmentation and calibration process for a rack enclosure intrusion breach detection system in accordance with various embodiments of this disclosure. Calibration of the rack enclosure intrusion breach detection system is performed on a projected light source and surrounding environment to create and calibrate baseline image segments. Such calibration may occur one time in a given environment, or may occur several times due to an environment change, such as changes in ambient light levels during the course of a day. Once a projected light source 810 is placed, it must be located within the field of view of a camera 620 (FIG. 6A) and the entire VIPM system calibrated to determine where the projected light source is located, characteristics of the projected light source image, and/or capturing of a baseline image segments of the projected light source for use during the image breach detection phase of the system.

A projected light terminator image is defined 800 where images of the projected light source 810 are captured and processed to define an image mask of the projected light source 810 for the baseline image. Logical and numerical operators isolate the image of the projected light source 810 from the surrounding environment based on the contrast of the projected light source 810. Such operators may be applied on a pixel by pixel basis. Examples of such operations may include subtracting, averaging, logical NOT, AND, and/or OR. This VIPM image isolation defines the projected light terminator image characteristics and process the image properties of the projected light source 810. Image properties of the projected light terminator image may include hue, saturations, and/or brightness that allow the system to distinguish the projected light terminator image from the remainder of the captured image. When complete, the projected light terminator may consist of an outline image of the projected light source.

Once the projected light terminator image is defined 800, it may be necessary for the VIPM to capture, correct, and/or validate the projected light terminator image 810. Image correction may be accomplished in a variety of ways. These may include, a series of morphological operations performed on the projected light terminator image. Such morphological operations utilize a collection of non-linear functions related to the shape or morphology of features in an image which may be utilized to determine an edge, remove noise, enhance, and/or segment an image. Examples of these operations include erosion and/or dilation.

It should be appreciated that various algorithm types are utilized to correct the projected light terminator image 810. Such algorithms may include, but are not limited to contour-finding algorithms. In various embodiments, the projected light source will appear as a continuous block of pixels in the projected light terminator image. This block of pixels may result in the definition of the corrected projected light terminator image 810 from the projected light terminator image.

In various embodiments, contour finding algorithms are utilized to find contiguous blocks of pixels within the projected light terminator image to determine which contours belong to the projected light terminator image and which do not. This calibration process assists in identification and creation of an image representation of the projected light source 810 or another mark.

Once a corrected projected light terminator image is determined, the VIPM defines a series of image segments from the corrected projected light terminator image 815 utilizing the segmentation and/or other process defined in FIGS. 6A-6D. A resulting series of image segments of the projected light source image is defined. These image segments may be processed together, individually, serially, and/or in parallel to reduce the amount of overall processing overhead necessary in the system. Embodiments contemplate processing may occur on an image by image basis, image segment by image segment basis, pixel by pixel basis, and/or contour by contour basis.

In one of many examples, the VIPM may implement a Delaunay triangulation to process the corrected projected light terminator image. This triangulation will create a triangular collection of image segments as illustrated in FIG. 6A. Image processing calculations performed during the detection may be reduced significantly as a result of processing the individual projected light source image segments or pixels instead of the entire projected light source 810. Once a collection of image segments 815 is defined, a segmented baseline image is established 820 which may be used for future image processing.

This established baseline segmented image 820 may require further processing and/or correction to refine the image to be utilized during the image breach detection process. It should be appreciated this processing and/or correction may occur on an image by image basis, a segment by segment basis, pixel by pixel basis, and/or contour by contour basis. FIG. 8B illustrates embodiments of a flow diagram for baseline image segment correction of a rack intrusion detection system. A baseline image segment being established 820 transitions to the baseline correction flow where one or more established baseline image segment(s) are characterized 845. Such characteristics of the one or more baseline image segment(s) may include hue, color saturation, and/or blurring. Other characteristics are contemplated in embodiments of this disclosure. The characteristics may be used as part of the calibration process for the one or more baseline image segment(s) and/or during the breach detection process to compare to an operational image segment and/or to determine when a recalibration of the baseline image segments may be desired.

Once the baseline image segments are characterized 845, a determination may be made if the existing baseline image segments are acceptable 850 for use as a baseline image segment during detection operations. Acceptability metrics may be established utilizing baseline image segment characteristics 845. For example, a determination of baseline acceptability 850 may be determined by an amount of image noise within the baseline image segment. It should also be appreciated that combinations of acceptable metrics may be utilized such as incomplete line segments, irregular contours, and/or adjustments to the environment such as automatic white balancing and/or contrast enhancement, in a determination of acceptability for a baseline image segment.

If it is determined the baseline is not acceptable, correction and/or adaptation of the baseline image segment 855 occurs to correct or adapt the deficiencies to the existing environment. These corrections/adaptations and may repeat until the baseline is determined acceptable, or until such time as the system determines another function, such as aborting the operation and/or utilizing the best available captured baseline. Several alternate functions are contemplated as part of this disclosure, such as time outs, user intervention, and/or external triggering events. Any deficiencies in the baseline image may be remedied utilizing methods detailed herein such as morphological, contour forming, and/or other video processing methods available.

Once the baseline is determined acceptable 850, a determination is made if a user will utilize a visible projected light source, an invisible boundary, or combination of visible and invisible as discussed above and illustrated in FIG. 2.

If a user or system determines a projected light source will remain visible and unchanged during detection operations, as is necessary throughout the baseline image calibration process, and the baseline image is determined acceptable 850, the VIPM transitions back to the calibration logic flow and a determination is made if the calibration is complete 830. If calibration is determined to be completed by a user or system, the VIPM transitions to the breach detection operation illustrated in FIG. 8C.

If a user or system determines a projected light source will be invisible (outside the visible light spectrum) during detection operations, the VIPM may utilize a non-visible source mode. A user will remove or change the visible projected light source and the VIPM must adapt and recalibrate the baseline image 855 to adjust for the change in environment. Principles of the disclosure contemplate while the visual projected light source is removed, the system retains the location of the projected light source segments and calculates a baseline for the projected light source segments with the new background, or no visible projected light source. This projected light source image is utilized to derive a new baseline image, along with existing images of the field of view to adjust for the surrounding environment. Image properties of the new baseline image are adapted/calibrated from the new environment of no visible projected light source. If the new baseline image is acceptable 850, the process transitions back to the calibration logic flow and a determination is made if the calibration is complete 830. If the calibration is determined to be completed 830, the system transitions to the detection operation illustrated in FIG. 8C.

FIG. 8C illustrates a VIPM implemented flow diagram detailing a breach detection process for a rack intrusion detection system. Once a VIPM has a calibrated, corrected, and validated baseline image segments as illustrated in FIGS. 8A and 8B, the system is commissioned and enters the image breach detection phase. Within the detection phase, characteristics of an operational image segment of the projected light source is evaluated against one or more characteristics of the established baseline image segments. This evaluation may include factors such as the environment, camera gain, and/or camera exposure. Embodiments of this disclosure contemplate autonomous adjustments to allow adaptation to the environment. It should be appreciated this evaluation may be accomplished on a complete image by complete image basis, image segment by image segment basis, pixel by pixel basis, and/or contour by contour basis.

An evaluation metric is determined 870 whether to trigger an alarm and/or event based on a metric calculated from one or more features and/or characteristics of the operational image segment. Principles of the disclosure contemplate evaluation of metrics such as average hue, number of pixels outside of an acceptable hue range, and/or other image or combination of image characteristics to evaluate an image. Embodiments of the disclosure utilize these evaluation metrics to reduce and/or eliminate false positive and/or false negative triggering of alarms and/or events.

Once the evaluation metric on an image by image, segment by segment, pixel by pixel, and/or contour by contour basis is determined 870, an evaluation of the characteristics of the corrected baseline image segments against the characteristics of the operational image segments 875 is processed. This comparison may be performed on an image by image, segment by segment, pixel by pixel, and/or contour by contour basis. It should be appreciated a pre-evaluation state may also occur where various filtering or processing of several images and/or image segments prior to applying the evaluation metric. This pre-processing may be utilized to assure robust image and/or image segment capture to avoid, for example, false positive, and/or false negative detection triggering. While part of the evaluation of the baseline against the operational image segment(s) 875, such a process may utilize methods not utilized during the actual evaluation.

During the evaluation, itself, the evaluation metric determined 870 is compared to a threshold metric for each segmented image derived during the segmentation and/or segmentation process illustrated in FIGS. 6A-6D. It should be appreciated a threshold metric may be created for the boundary image as a whole, where there is a single threshold. Further, individual image segments may themselves have independent thresholds. A combination is also contemplated where some image segments may share a threshold value where others remain independent of any other. Embodiments of the system contemplate an autonomous determination of threshold based on the baseline image characteristics, operational image segment characteristics, environment, and/or other facts which impact image processing.

Alternate embodiments contemplate utilizing a number of image segments or adjacent image segments as a feature to be utilized to determine an alert threshold. Further, a number of consecutive operational images where the boundary has appeared to have been breached may be utilized to determine an alert threshold.

It should be appreciated the image capture of the operational image segments may utilize various settings within the camera system. As detailed previously, due to the ability of embodiments of the system to create simpler image processing a wide range of acceptable camera settings are possible in various embodiments. As one of many examples, to accomplish robust detection from a baseline, a commercial off the shelf camera may be utilized at a framerate of 30 frames per second and an image size of 640×400 pixels. Other frame rates and image resolutions are contemplated as part of this disclosure.

Further, cameras with higher capabilities may be used, but may not be necessary in various embodiments. Principles of the disclosure contemplate the use of multiple lower capability cameras, in substitute of a single higher capability camera. In this way, further cost reduction is possible with the replacement of very high cost cameras and associated optics with no sacrifice of robust image detection.

A baseline image segment may be dynamic in nature and may be adaptable vary based on environmental conditions such as lighting, movement, and/or other conditions that may cause an image or image segment to change over time. It is beneficial to determine if the baseline image or image segment requires recalibration 880. Examples of when a recalibration may be beneficial may include determining whether a predetermined period of time has passed since the last calibration, lighting conditions have deviated by a predetermined amount, and/or other cause as determined by a user and/or the system. If it is determined recalibration will occur processing transitions to the calibration flow as illustrated in FIG. 8A.

If no recalibration will occur, a decision is made if there are changes to the baseline image or image segment 885. If no changes to the baseline, no action is taken and the system continues to evaluate the baseline image characteristics against the operational image or image segment characteristics 875. If, however the operational boundary differs from the baseline, which should result in a trigger, the system may communicate the changes to a management device 890, user, or other system to remediate the matter further.

Once this communication to a management device 890 occurs, the system continues to evaluate the baseline image or image segment characteristics against the operational image characteristics 875 until such time a user or the system determines another logic flow.

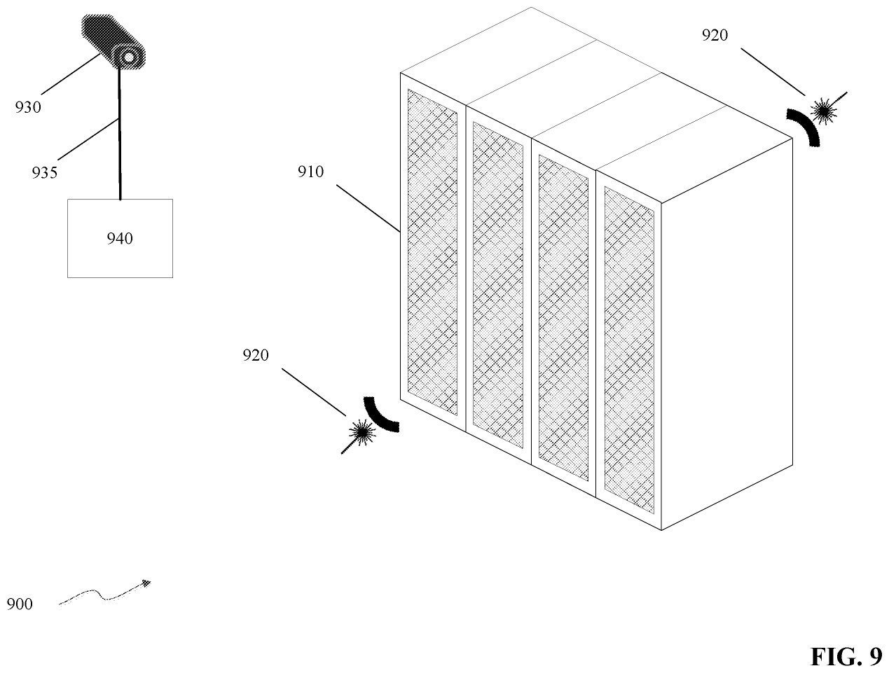

FIG. 9 illustrates an isometric view of a rack intrusion detection system 900 including one camera and a plurality of projected light sources in accordance with various embodiments of this disclosure. Embodiments of a system may include a plurality of rack enclosures 910, a pair of projected light sources 920, a camera 930, a computer system to process the video images produced by the camera 930, and a Video Image Processing Module (VIPM) 940, connected by a data and/or power connection 935, such as Power Over Ethernet (POE) or other data only standard, wired or wireless in nature.

As one of many embodiments, the pair of projected light source 920 is placed in front of the plurality of rack enclosures 910, a camera 930 will create a baseline image or image segment utilizing embodiments of the process illustrated in FIG. 8A-8C. Once both calibration and correction of the baseline image or image segments are completed, the system will be ready to alert one or more users and/or take autonomous action if a detection occurs from a deviation between the established baseline and operational images or image segments.

In operation, for example, once a system for rack intrusion detection 900 is calibrated and corrected to detect any deviation from the established baseline, if any object were to pass into the frame of the camera 930 and onto the projected light source 920, a series of events could be commenced to both alert security of an authorized entry and act to cease any further intrusion or prevent further access to the computer equipment located in the plurality of rack enclosures 910. Such activity may fall into alerting and/or preventing further access as well as identifying the existing intrusion.

Alerting the intrusion may take on many forms that include, but are not limited to autonomously flashing a beacon on a rack or room to alert personnel of an intrusion. Audible indicators such as sirens or loud speaker announcements may also be used. Existing management systems may be utilized to contact appropriate personnel via voice message, text, email, and/or any other appropriate means, utilizing any established priority of users or delegation of authority.

Intrusion limiting activities may include, locking any rack enclosures not currently locked to prevent any further intrusions. Further, if any room doors are unlocked or other access control vestibule devices in use, they may be disabled/enabled to retain any intrusion to a particular area. Other autonomous activities may include stopping all data transfer to and/or from the rack enclosure that may be compromised or some and/or all data to a particular facility or part of the building. In this way, if a rack enclosure was accessed to deliver a malicious data payload, it would not be allowed to transmit to other machines.

Regarding identification, cameras may be trained onto the intrusion site and autonomously commanded to increase their frame rates to maximum in an attempt to capture all details possible. If other cameras are able to be trained onto the intrusion site, a command to any adjustable (Pan-Tilt-Zoom) camera may be utilized to not only obtain as much visual evidence as possible, but also track the intrusion if it were to move. In this way, an accurate reporting of where an intrusion source is may be collected and given to the appropriate authorities.

It should be appreciated the above scenario is exemplary only and many such schemes are possible utilizing the autonomous alerting and/or actions within a system for rack intrusion detection 900.

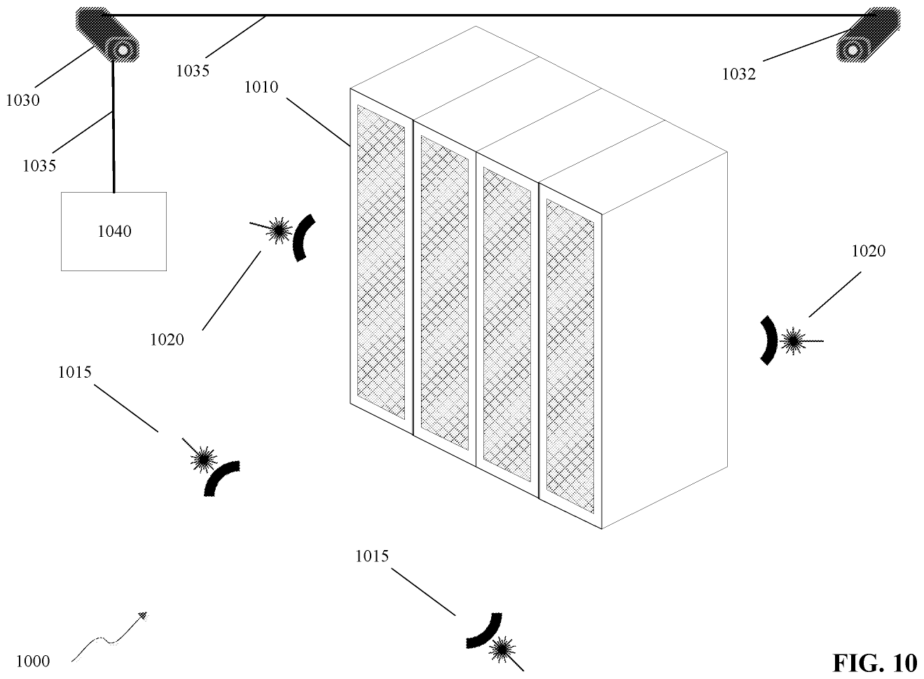

FIG. 10 illustrates an isometric view of embodiments of a rack intrusion detection system 1000 including a plurality of cameras and projected light sources in accordance with various embodiments of this disclosure. Embodiments of a system may include a plurality of rack enclosures 1010, a plurality of visible spectrum projected light sources 1015, a plurality of non-visible spectrum projected light sources 1020, a plurality of cameras 1030, 1032, and a Video Image Processing Module (VIPM) 1040, connected by a data and/or power connection 1035, such as Power Over Ethernet (POE) or other data only standard, wired or wireless in nature. Embodiments of the system contemplate a combination of visible and invisible spectrum projected light sources which may correlate to security levels.

Such an embodiment may be configured in accordance with the embodiment illustrated in FIG. 8A-8C. Both a visible spectrum projected light source 1015 calibration and non-visible spectrum projected light source calibration 1020 will occur where the system will determine a baseline image and/or image segments. Once the calibration and commissioning are completed, the system will enter the detection phase to determine a breach to the visible and non-visible spectrum projected light sources.

It should be appreciated that one or more cameras may be used in a rack intrusion detection system 1000. These cameras may operate independent of each other such as maintaining a single field of view, and/or in collaboration with another camera should a projected light source require more than one camera to capture the entire boundary, and/or to provide a level of redundancy.

General purpose computer components may be used and configured as components of a rack intrusion detection system. Such computer systems may be used in various embodiments of this disclosure, for example, general-purpose computers such as those based on Intel PENTIUM-type processor, Motorola PowerPC, Sun UltraSPARC, Hewlett-Packard PA-RISC processors, or any other type of processor.

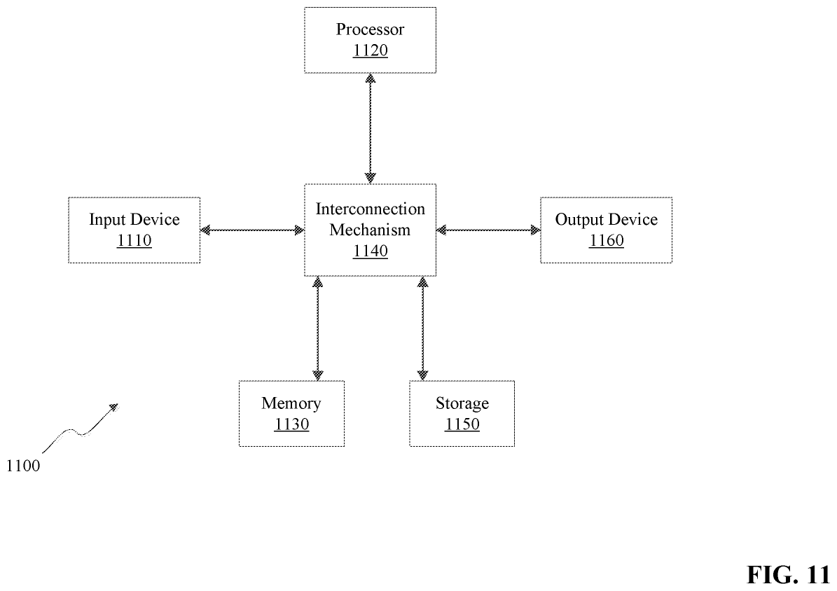

For example, various embodiments of the rack intrusion detection system may utilize or be implemented utilizing specialized software executing in computer system components 1100 such as that shown in FIG. 11. Embodiments of this computer system components 1100 may be general-purpose in nature. The computer system components 1100 may include a processor 1120 connected to one or more memory devices 1130, such as a disk drive, memory, or other device for storing data. Memory 1130 is typically used for storing programs and data during operation of the computer system components 1100. The computer system components 1100 may also include a storage system 1150 that provides additional storage capacity. Components of computer system 1100 may be coupled by an interconnection mechanism 1140, which may include one or more busses (e.g., between components that are integrated within the same machine) and/or a network (e.g., between components that reside on separate discrete machines). The interconnection mechanism 1140 enables communications (e.g., data, instructions) to be exchanged between computer system components 1100.

Computer system components 1100 also includes one or more input devices 1110, for example, a keyboard, mouse, trackball, microphone, touch screen, and one or more output devices 1160, for example, a printing device, display screen, speaker. In addition, computer system 1100 may contain one or more interfaces (not shown) that connect computer system 1100 to a communication network (in addition or as an alternative to the interconnection mechanism 1140).

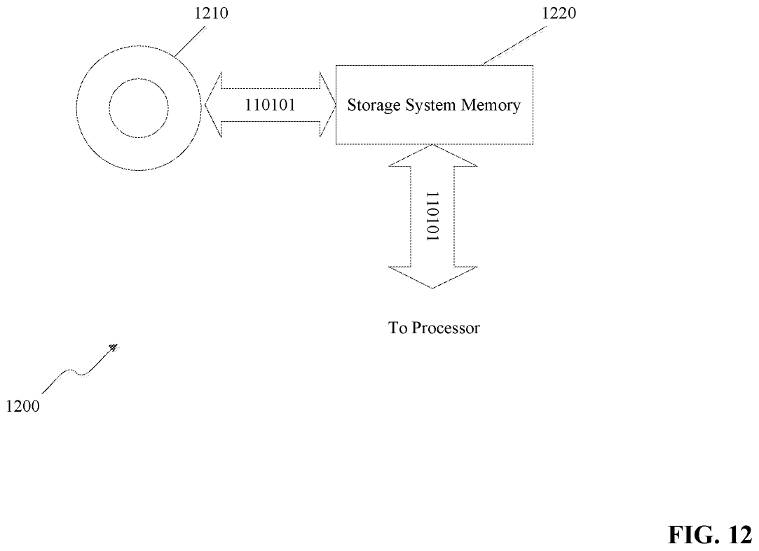

The storage system, which is indicated at 1200 and shown in greater detail in FIG. 12, typically includes a computer readable and writeable nonvolatile recording medium 1210 in which signals are stored that define a program to be executed by the processor or information stored on or in the medium 1210 to be processed by the program to perform one or more functions associated with embodiments described herein. The medium may, for example, be a disk or flash memory. Typically, in operation, the processor causes data to be read from the nonvolatile recording medium 1210 into another memory 1220 that allows for faster access to the information by the processor than does the medium 1210. This memory 1220 is typically a volatile, random access memory such as a dynamic random-access memory (DRAM) or static memory (SRAM). It may be located in storage system 1200, as shown, or in memory system 1130. The processor 1120 generally manipulates the data within the integrated circuit memory 1130, 1220 and then copies the data to the medium 1210 after processing is completed. A variety of mechanisms are known for managing data movement between the medium 1210 and the integrated circuit memory element 1130, 1220, and the disclosure is not limited thereto. The disclosure is not limited to a particular memory system 1130 or storage system 1150.

The computer system may include specially-programmed, special-purpose hardware, for example, an Application Specific Integrated Circuit (ASIC). Aspects of the disclosure may be implemented in software, hardware or firmware, or any combination thereof. Further, such methods, acts, systems, system elements and components thereof may be implemented as part of the computer system described above or as an independent component.

Although computer system 1100 is shown by way of example as one type of computer system upon which various aspects of the disclosure may be practiced, it should be appreciated that aspects of the disclosure are not limited to being implemented on the computer system as shown in FIG. 12. Various aspects of the disclosure may be practiced on one or more computers having a different architecture or components shown in FIG. 12. Further, where functions or processes of embodiments of the disclosure are described herein (or in the claims) as being performed on a processor or controller, such description is intended to include systems that use more than one processor or controller to perform the functions.

Computer system 1100 may be a general-purpose computer system that is programmable using a high-level computer programming language. Computer system 1100 may be also implemented using specially programmed, special purpose hardware. In computer system 1100, processor 1120 is typically a commercially available processor such as the well-known Pentium class processor available from the Intel Corporation. Many other processors are available. Such a processor usually executes an operating system which may be, for example, the Windows 95, Windows 98, Windows NT, Windows 2000, Windows ME), Windows XP, Vista, or Windows 7, or progeny operating systems available from the Microsoft Corporation, MAC OS System X, or progeny operating system available from Apple Computer, the Solaris operating system available from Sun Microsystems, UNIX, Linux (any distribution), or progeny operating systems available from various sources. Many other operating systems may be used.

The processor and operating system together define a computer platform for which application programs in high-level programming languages are written. It should be understood that embodiments of the disclosure are not limited to a particular computer system platform, processor, operating system, or network. Also, it should be apparent to those skilled in the art that the present disclosure is not limited to a specific programming language or computer system. Further, it should be appreciated that other appropriate programming languages and other appropriate computer systems could also be used.

One or more portions of the computer system may be distributed across one or more computer systems coupled to a communications network. For example, as discussed above, a computer system that determines available power capacity may be located remotely from a system manager. These computer systems also may be general-purpose computer systems. For example, various aspects of the disclosure may be distributed among one or more computer systems configured to provide a service (e.g., servers) to one or more client computers, or to perform an overall task as part of a distributed system. For example, various aspects of the disclosure may be performed on a client-server or multi-tier system that includes components distributed among one or more server systems that perform various functions according to various embodiments of the disclosure. These components may be executable, intermediate (e.g., In Line) or interpreted (e.g., Java) code which communicate over a communication network (e.g., the Internet) using a communication protocol (e.g., TCP/IP). For example, one or more database servers may be used to store device data, such as expected power draw, that is used in designing layouts associated with embodiments of the present disclosure.

It should be appreciated that the disclosure is not limited to executing on any particular system or group of systems. Also, it should be appreciated that the disclosure is not limited to any particular distributed architecture, network, or communication protocol.

Various embodiments of the present disclosure may be programmed using an object-oriented programming language, such as SmallTalk, Java, C++, Ada, or C# (C-Sharp). Other object-oriented programming languages may also be used. Alternatively, functional, scripting, and/or logical programming languages may be used, such as BASIC, ForTran, COBoL, TCL, or Lua. Various aspects of the disclosure may be implemented in a non-programmed environment (e.g., documents created in HTML, XML or other format that, when viewed in a window of a browser program render aspects of a graphical-user interface (GUI) or perform other functions). Various aspects of the disclosure may be implemented as programmed or non-programmed elements, or any combination thereof.

Embodiments of a systems and methods described above are generally described for use in relatively large data centers having numerous equipment racks; however, embodiments of the disclosure may also be used with smaller data centers and with facilities other than data centers. Some embodiments may also be a very small number of computers distributed geographically so as to not resemble a particular architecture.

In embodiments of the present disclosure discussed above, results of analyses are described as being provided in real-time. As understood by those skilled in the art, the use of the term real-time is not meant to suggest that the results are available immediately, but rather, are available quickly giving a designer the ability to try a number of different designs over a short period of time, such as a matter of minutes.

Having thus described several aspects of at least one embodiment of this disclosure, it is to be appreciated various alterations, modifications, and improvements will readily occur to those skilled in the art. Such alterations, modifications, and improvements are intended to be part of this disclosure, and are intended to be within the spirit and scope of the disclosure. Accordingly, the foregoing description and drawings are by way of example only.

What is claimed is:

1. A system of detecting intrusion into a rack enclosure, the system comprising:
a rack enclosure;
a projected light source;
a video camera configured to capture and transmit image data;
a Video Image Processing Module (VIPM) configured to receive and process image data from the video camera and communicate image data changes; and
a management device configured to receive and process image data changes.

2. The system of claim 1, further comprising a plurality of rack enclosures.

3. The system of claim 1, further comprising a plurality of projected light sources.

4. The system of claim 3, wherein the plurality of projected light sources is visible light.

5. The system of claim 3, wherein the plurality of projected light sources is IR light.

6. The system of claim 1, further comprising a plurality of video cameras.

7. The system of claim 1, further comprising a plurality of VIPMs.

8. A system of detecting intrusion into a rack enclosure, comprising:
a processor configured to
extract a projected light terminator image from a captured image,
perform image correction operations on the projected light terminator image,
process the projected light terminator image utilizing image processing operations to determine a corrected projected light terminator image,
determine a collection of image segments based on the corrected projected light terminator image,
establish one or more baseline image metrics of the collection of image segments,
evaluate the one or more baseline image metrics for changes with operational image segment characteristics, and
communicate any baseline image metric changes to a management device.

9. The system of claim 8, wherein the corrected projected light terminator image is processed to form a regular segmentation.

10. The system of claim 8, wherein the corrected projected light terminator image is processed to form a semi-regular segmentation.

11. The system of claim 8, wherein the corrected projected light terminator image is processed to form a demi-regular segmentation.

12. The system of claim 8, wherein the corrected projected light terminator image is processed to form a segmented image.

13. The system of claim 8, wherein the corrected projected light terminator image is dynamically shifted in time.

14. The system of claim 8, further comprising
a projected light source, and
a video camera configured to capture and transmit image data.

15. A method of detecting intrusion into a rack enclosure, comprising:
projecting light from a light source;
capturing and transmitting a captured image;
extracting, a projected light terminator image from the captured image;
performing, image correction operations on the projected light terminator image;
processing, the projected light terminator image utilizing image processing operations to determine a corrected projected light terminator image;
determining, a collection of image segments based on the corrected projected light terminator image;
establishing, one or more baseline image metrics of the collection of image segments;
evaluating, the one or more baseline image metrics for changes with operational image segment characteristics; and
communicating, any baseline image metric changes to a management device.

16. The method of claim 15, wherein the corrected projected light terminator image is processed to form a regular segmentation.

17. The method of claim 15, wherein the corrected projected light terminator image is processed to form a semi-regular segmentation.

18. The method of claim 15, wherein the corrected projected light terminator image is processed to form a demi-regular segmentation.

19. The method of claim 15, wherein the corrected projected light terminator image is processed to form a segmented image.

20. The method of claim 15, wherein the corrected projected light terminator image is dynamically shifted in time.
